(19) United States
(12) Patent Application Publication
(10) Pub. No.: US 2014/0238479 A1
(43) Pub. Date: Aug. 28, 2014

(54) THIN FILM SOLAR CELL

(71) Applicant: Electronics and Telecommunications Research Institute, Daejeon (KR)

(72) Inventors: JungWook LIM, Daejeon (KR); Sun Jin YUN, Daejeon (KR); Seong Hyun LEE, Busan (KR)

(73) Assignee: Electronics and Telecommunications Research Institute, Daejeon (KR)

(21) Appl. No.: 14/179,067

(22) Filed: Feb. 12, 2014

(30) Foreign Application Priority Data
Feb. 27, 2013 (KR) 10-2013-0021444

(51) Int. Cl. H01L 31/0216

(52) U.S. Cl. CPC H01L 31/02167
USPC 136/256

(57) ABSTRACT

Provided is a thin film solar cell including a rear electrode formed on a substrate, a light absorbing layer formed on the rear electrode, a buffer layer formed on the light absorbing layer, and a front transparent electrode formed on the buffer layer. The buffer layer includes copper oxide.

### CROSS-REFERENCE TO RELATED APPLICATIONS

This U.S. non-provisional patent application claims priority under 35 U.S.C. §119 of Korean Patent Application No. 10-2013-0021444, filed on Feb. 27, 2013, the entire contents of which are hereby incorporated by reference.

### BACKGROUND

The present disclosure herein relates to a thin film solar cell and a method of manufacturing the same, and more particularly, to a buffer layer of a compound thin film solar cell and a method of manufacturing the same.

A solar cell is a photovoltaic energy conversion system for converting sunlight into electric energy. In the solar cell, the sunlight is used as an energy source of generating electricity, and the sunlight may be a clean energy source, which generate no harmful materials. Therefore, the sunlight gets the limelight as a typical environment-friendly future energy source, which may replace fuel materials, and researches on the development of the solar cell are increasing.

A thin film solar cell may include an amorphous or crystalline silicon thin film solar cell, a CIGS-based thin film solar cell, and a CdTe thin film solar cell. Among them, the CIGS-based thin film solar cell is included in a compound semiconductor solar cell. A CIGS light absorbing layer is formed by using a material obtained by adding Ga into a CIS compound semiconductor to increase a band gap. Through controlling the amount of Ga, the band gap may be controlled. The light absorbing layer of the CIGS-based thin film solar cell includes II-III-VI₂ group compound semiconductor represented by CuInSe₂ (CIS), has a direct transition type energy band gap, and has high light absorption coefficient. Therefore, a solar cell having high efficiency may be manufactured by a thin film of about 1 μm to 2 μm.

### SUMMARY

The present disclosure provides a thin film solar cell having improved efficiency.

The present disclosure is not limited to the above-described aspect, and another aspect will be clearly understood by a person skilled in the art from the following description.

Embodiments of the inventive concept provide a thin film solar cell including a rear electrode formed on a substrate, a light absorbing layer formed on the rear electrode, a buffer layer formed on the light absorbing layer, and a front transparent electrode formed on the buffer layer. The buffer layer includes copper oxide.

In some embodiments, the copper oxide may be CuₓO_{y} (0<x≦2.5, and 0<y≦1.5).

In other embodiments, y of the copper oxide may be the same in the buffer layer, and x of the copper oxide may be gradually increased from an interface of the buffer layer with the front transparent electrode to an interface of the buffer layer with the light absorbing layer.

In still other embodiments, y of the copper oxide may be the same in the buffer layer, and x of the copper oxide may be gradually decreased from an interface of the buffer layer with the front transparent electrode to an interface of the buffer layer with the light absorbing layer.

In even other embodiments, the buffer layer may have refractive index, and the refractive index of the buffer layer may be increased as an increase of x of the copper oxide.

In yet other embodiments, the buffer layer may have an energy band gap of from about 1.15 eV to about 2.8 eV.

In further embodiments, the buffer layer may have gradually increasing energy band gap from an interface of the buffer layer with the front transparent electrode to an interface of the buffer layer with the light absorbing layer.

In still further embodiments, the buffer layer may have gradually decreasing energy band gap from an interface of the buffer layer with the front transparent electrode to an interface of the buffer layer with the light absorbing layer.

In even further embodiments, the buffer layer may have n-type semiconductor properties, and migration of electrons may be easier than migration of holes from the light absorbing layer to the buffer layer.

In yet further embodiments, the buffer layer may have p-type semiconductor properties, and migration of holes may be easier than migration of electrons from the light absorbing layer to the buffer layer.

In much further embodiments, the buffer layer may include a first buffer layer and a second buffer layer stacked on the light absorbing layer one by one, and the first buffer layer may include copper oxide.

In still much further embodiments, the second buffer layer may include ZnS or ZnOS.

A buffer layer of a thin film solar cell according to an embodiment of the inventive concept is formed by using copper oxide, and no adverse effect on environmental contamination may be induced. In addition, since the buffer layer has a continuously varying energy band gap, electrons and holes formed in a light absorbing layer may be effectively collected. Therefore, a thin film solar cell having an improved efficiency may be formed.

### BRIEF DESCRIPTION OF THE DRAWINGS

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIG. 1 is a cross-sectional view of a thin film solar cell according to an embodiment of the inventive concept;

FIG. 2 is a cross-sectional view of a thin film solar cell according to another embodiment of the inventive concept;

FIGS. 3A and 3B are graphs illustrating energy band gaps between a buffer layer and a light absorbing layer according to the properties of the buffer layer in a thin film solar cell according to an embodiment of the inventive concept;

FIG. 4 is a graph illustrating transmittance with respect to the thickness of a copper oxide (Cu_{2+δ}O_{y}) thin film in a thin film solar cell according to an embodiment of the inventive concept;

FIG. 5 is a flowchart illustrating a method of manufacturing a thin film solar cell according to an embodiment of the inventive concept; and

FIGS. 6A to 6D are cross-sectional views illustrating a method of manufacturing a thin film solar cell according to an embodiment of the inventive concept.

### DETAILED DESCRIPTION OF THE EMBODIMENTS

Exemplary embodiments of the inventive concept will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art. Like reference numerals refer to like elements throughout.

The terminology used herein is for the purpose of describing particular example embodiments only and is not intended to be limiting of the present inventive concept. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations and/or planar illustrations that are schematic illustrations of idealized example embodiments. In the drawings, the dimensions of layers and regions are exaggerated for clarity of illustration. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, a region illustrated as a rectangle will, typically, have rounded or curved features. Thus, the regions illustrated in the figures are schematic in nature and their shapes are not intended to illustrate the actual shape of a region of a device and are not intended to limit the scope of the present inventive concept.

Hereinafter, exemplary embodiments of the inventive concept will be described in detail with reference to the accompanying drawings.

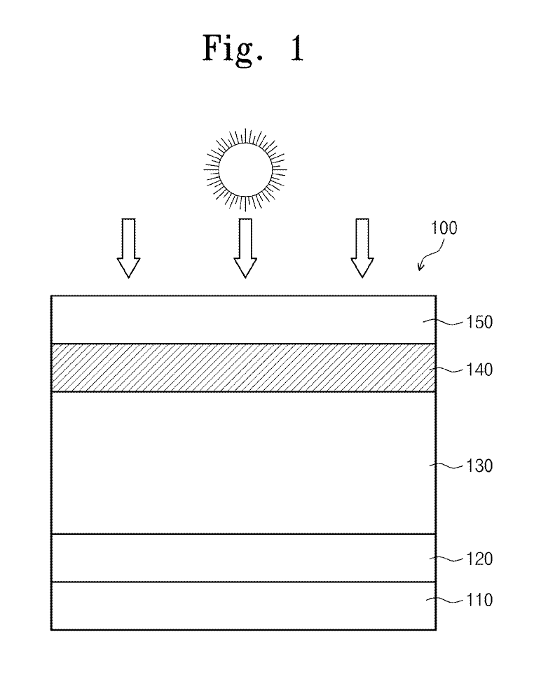

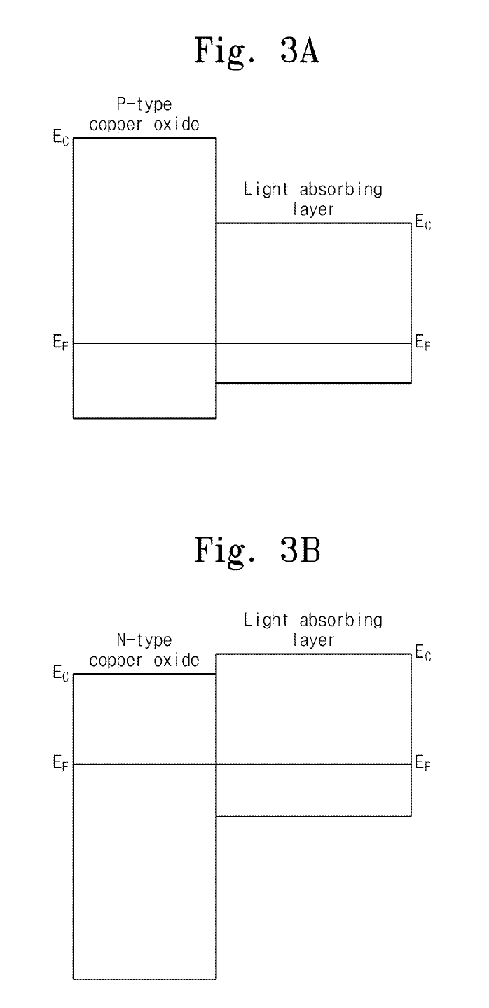

FIG. 1 is a cross-sectional view of a thin film solar cell according to an embodiment of the inventive concept. FIGS. 3A and 3B are graphs illustrating energy band gaps between a buffer layer and a light absorbing layer according to the properties of the buffer layer in a thin film solar cell according to an embodiment of the inventive concept.

Referring to FIG. 1, in a thin film solar cell 100, a rear electrode 120, a light absorbing layer 130, a buffer layer 140, and a front transparent electrode 150 are formed on a substrate 110 one by one. The thin film solar cell 100 is a compound semiconductor solar cell.

The substrate 110 may be a sodalime glass substrate. The sodalime glass substrate includes sodium (Na). Na included in the sodalime substrate is diffused into the light absorbing layer 130 of the compound semiconductor solar cell 100 and contributes to the improvement of the crystal system of the light absorbing layer 130. Accordingly, the photoelectric transformation efficiency of the compound semiconductor solar cell 100 may be increased. On the other hands, the substrate 110 may be a ceramic substrate such as alumina (Al₂O₃), and quartz, a metal substrate such as stainless steel, a Cu tape, chromium (Cr) steel, Kovar which is an alloy of nickel (Ni) and iron (Fe), titanium (Ti), ferritic steel, molybdenum (Mo), and the like, or a flexible polymer film such as a polyester film or a polyimide film (for example, Upilex, ETH-PI).

The rear electrode 120 may be formed by using a metal material. The rear electrode 120 may be formed by using a material having a small difference of thermal expansion coefficient with respect to the substrate 110 to prevent the generation of exfoliation phenomenon from the substrate 110. The rear electrode 110 may be formed by using, for example, Mo. Mo has high electric conductivity, forming properties of ohmic contact with other thin film, and stability at a high temperature in a selenium (Se) atmosphere.

The light absorbing layer 130 may be formed by using II-III-VI₂ group compound semiconductor.

According to an embodiment of the inventive concept, the light absorbing layer 130 may be a CIGS-based light absorbing layer formed by using, for example, CuInSe₂, Cu(In,Ga)Se₂, Cu(Al,In)Se₂, Cu(Al,Ga)Se₂, Cu(In,Ga)(S,Se)₂, (Au,Ag,Cu)(In,Ga,Al)(S,Se)₂. The CIGS-based light absorbing layer may be a compound semiconductor light absorbing layer in which a portions of an element in group II including Cu, an element in group III including In, and an element in group IV including Se may be replaced with other element in the same group. According to another embodiment of the inventive concept, the light absorbing layer 130 may be a CZTS light absorbing layer formed by using, for example, Cu₂ZnSn(S,Se)₄. The light absorbing layer 130 may be a chalcopyrite-based compound semiconductor. The light absorbing layer 130 may have an energy band gap of from about 1.15 eV to about 1.2 eV.

The buffer layer 140 may be formed by using copper oxide (CuₓO_{y}). X in the copper oxide (CuₓO_{y}) may be 0<x≦2.5, and y in the copper oxide (CuₓO_{y}) may be 0<y≦1.5. For example, the copper oxide (CuₓO_{y}) may be CuO or Cu₂O. Preferably, the buffer layer 140 has an energy band gap positioned in the middle of the light absorbing layer 130 and the front transparent electrode 150. For example, the buffer layer 140 may have the energy band gap of from about 1.5 eV to about 2.8 eV. The energy band gap of the copper oxide (CuₓO_{y}) may be changed according to the composition of copper (Cu) and oxygen (O). The buffer layer 140 may have a thickness of from about 5 nm to about 1,000 nm Preferably, the buffer layer 140 may have a thickness of from about 5 nm to about 100 nm. According to an embodiment of the inventive concept, the buffer layer 140 may be formed by using copper oxide (CuₓO_{y}), in which x and y may have a constant value. Thus, the energy band gap of the buffer layer 140 may be the same irrespective of the position of the buffer layer 140.

According to another embodiment of the inventive concept, the buffer layer 140 may be formed by using copper oxide (CuₓO_{y}), in which x may vary gradually. Particularly, y of the copper oxide may be the same within the buffer layer 140, and x of the copper oxide may be increased from the interface of the buffer layer 140 with the front transparent electrode 150 to the interface of the buffer layer 140 with the light absorbing layer 130. The energy band gap of the copper oxide (CuₓO_{y}) may increase as the x of the copper oxide increases. Therefore, the energy band gap of the buffer layer 140 may be gradually increased from the front transparent electrode 150 to the light absorbing layer 130. Alternatively, x of the copper oxide may be decreased from the interface of the buffer layer 140 with the front transparent electrode 150 to the interface of the buffer layer 140 with the light absorbing layer 130. In this case, the energy band gap of the buffer layer 140 may be gradually decreased from the front transparent electrode 150 to the light absorbing layer 130. An internal electric field may be formed in the buffer layer 140 due to the difference of the energy band gap in the buffer layer 140, and the charge formed in the light absorbing layer 130 may be effectively collected. In this case, the open-circuit voltage and the short-circuit current of the thin film solar cell may be improved. In addition, the refractive index of the buffer layer 140 may be gradually changed as x of the copper oxide varies gradually. For example, as x of the copper oxide is gradually increased, the refractive index of the buffer layer 140 may be gradually increased. Thus, the buffer layer 140 may have the gradient of the refractive index, and function as an antireflective layer.

The buffer layer 140 may be an n-type semiconductor or a p-type semiconductor. Generally, the copper oxide (CuₓO_{y}) illustrates the p-type without doping of external dopant. However, the copper oxide (CuₓO_{y}) may illustrate the n-type depend on the thickness and the process conditions of the copper oxide (CuₓO_{y}). For example, when the copper oxide (CuₓO_{y}) is formed by the same process conditions, the copper oxide (CuₓO_{y}) having a large thickness may illustrate the p-type, and the copper oxide (CuₓO_{y}) having a small thickness may illustrate the n-type.

Referring to FIGS. 3A and 3B, FIG. 3A is an energy band gap structure between the light absorbing layer 130 and the buffer layer 140 when the copper oxide (CuₓO_{y}) is the p-type semiconductor, and FIG. 3B is an energy band gap structure between the light absorbing layer 130 and the buffer layer 140 when the copper oxide (CuₓO_{y}) is the n-type semiconductor. In FIG. 3A, the migration of holes from the light absorbing layer 130 to the buffer layer 140 is easier than the migration of electrons. On the contrary, in FIG. 3B, the migration of electrons from the light absorbing layer 130 to the buffer layer 140 is easier than the migration of holes. For example, in FIG. 3A, the collection of the holes in the buffer layer 140 may be easy, and the open-circuit voltage properties of the solar cell may be improved. In FIG. 3B, the collection of the electrons in the buffer layer 140 may be easy, and the short-circuit current of the solar cell may be improved. That is, the buffer layer 140 may affect the efficiency of the solar cell through affecting the solar cell due to the recombination of the electrons and the holes according to the properties of the n-type or the properties of the p-type. Considering the above properties, the properties of the thin film solar cell 100 may be diversely controlled.

Commonly used cadmium sulfide (CdS) used as the material of the buffer layer 140 is toxic, however the copper oxide (CuₓO_{y}) is non-toxic. When the copper oxide (CuₓO_{y}) is used for the formation of the buffer layer 140, no influence on environmental contamination may be generated. In addition, since the buffer layer 140 has a continuously varying energy band gap, the electrons and the holes formed in the light absorbing layer 130 may be effectively collected. Thus, a thin film solar cell 100 having an improved efficiency may be formed.

Referring to FIG. 1 again, the front transparent electrode 150 may be formed at the front side of the thin film solar cell 100 and may function as a window. Thus, the front transparent electrode 150 may be formed by using a material having high light transmittance and high electric conductivity. For example, the front transparent electrode 150 may be formed as a zinc oxide (ZnO) layer. The zinc oxide layer may have an energy band gap of about 3.3 eV, and high light transmittance of about 80% or above. The zinc oxide layer may be doped with aluminum (Al) or boron (B) and may have a low resistance value of about 1×10⁻⁴ Ωcm. When the zinc oxide layer is doped with boron (B), the light transmittance at near infrared region may be increased, and the short-circuit current may be increased.

Alternatively, an indium tin oxide (ITO) thin film having good electro-optical properties may be further included on the ZnO thin film in the front transparent electrode 150. The front transparent electrode 150 may be a stacked layer of an undoped i-type (intrinsic semiconductor) ZnO thin film, and an n-type ZnO thin film having a low resistance formed thereon.

On the front transparent electrode 150, an antireflective layer (not illustrated) and a grid electrode (not illustrated) may be further disposed. The antireflective layer may reduce the reflection loss of sunlight incident to the thin film solar cell 100. The antireflective layer may be formed by using, for example, MgF₂. The grid electrode may be provided to collect current at the surface of the thin film solar cell 100. The grid electrode may increase the conductivity of the front transparent electrode 150. The grid electrode may be formed by using a metal such as aluminum (Al), or nickel (Ni)/aluminum (Al).

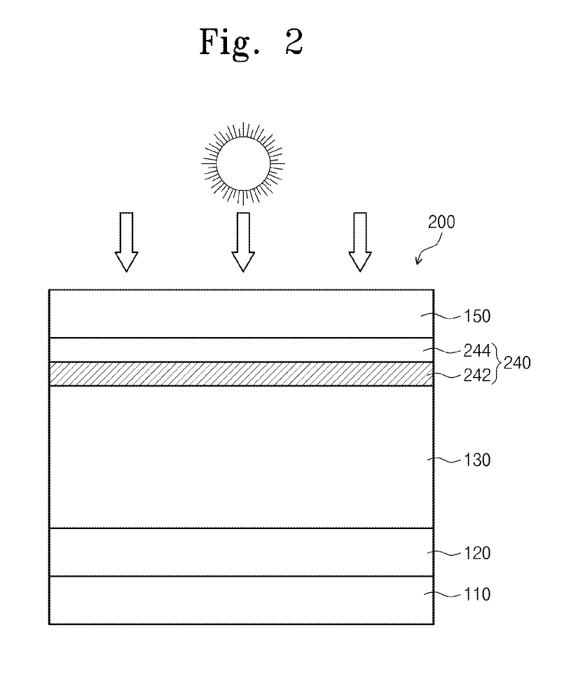

FIG. 2 is a cross-sectional view of a thin film solar cell according to another embodiment of the inventive concept.

For brevity of explanation, the same reference numeral was used for substantially the same elements as in the above embodiment of the inventive concept, and the explanation on corresponding elements will be omitted.

In a thin film solar cell 200, a rear electrode 120, a light absorbing layer 130, a buffer layer 240, and a front transparent electrode 150 are formed on a substrate 110 one by one. The thin film solar cell 200 is a compound semiconductor solar cell.

The buffer layer 240 includes a first buffer layer 242 and a second buffer layer 244. The first buffer layer 242 and the second buffer layer 244 may be stacked on the light absorbing layer 130 one by one. Preferably, the buffer layer 240 has an energy band gap positioned in the middle of the light absorbing layer 130 and the front transparent electrode 150. For example, the buffer layer 240 may have an energy band gap of from about 1.5 eV to about 3.0 eV.

The first buffer layer 242 may be formed by using copper oxide (CuₓO_{y}). The first buffer layer 242 may have an energy band gap of from about 1.5 eV to about 2.8 eV. X in the copper oxide (CuₓO_{y}) may be 0<x≦2.5, and y in the copper oxide (CuₓO_{y}) may be 0<y≦1.5. In an embodiment of the inventive concept, the first buffer layer 242 may be the copper oxide (CuₓO_{y}) having constant values of x and y. Thus, the energy band gap of the first buffer layer 242 may be the same through the entire position of the first buffer layer 242.

In an embodiment of the inventive concept, the first buffer layer 242 may be formed by using copper oxide (CuₓO_{y}), in which x may vary gradually. Particularly, when y of the copper oxide may be the same within the first buffer layer 242, x of the copper oxide in the first buffer layer 242 may be increased from the interface of the first buffer layer 242 with the second buffer layer 244 to the interface of the first buffer layer 242 with the light absorbing layer 130. The energy band gap of the copper oxide (CuₓO_{y}) increases as the x of the copper oxide increases. Therefore, the energy band gap of the first buffer layer 242 may be gradually increased from the second buffer layer 244 to the light absorbing layer 130. Alternatively, x of the copper oxide in the first buffer layer 242 may be decreased from the interface of the first buffer layer 242 with the second buffer layer 244 to the interface of the first buffer layer 242 with the light absorbing layer 130. In this case, the energy band gap of the first buffer layer 242 may be gradually decreased from the second buffer layer 244 to the light absorbing layer 130. The first buffer layer 242 may be an n-type or a p-type.

The second buffer layer 244 may include ZnS or ZnOS. The second buffer layer 244 may be the n-type. The second buffer layer 244 may have an energy band gap of from about 2.5 eV to about 3.0 eV. In an embodiment of the inventive concept, the component ratio of sulfur (S) and oxygen (O) in ZnOS may be constant. In another embodiment of the inventive concept, the component ratio of sulfur (S) and oxygen (O) may be different. For example, the component ratio of sulfur (S) in ZnOS may be increased or decreased from the front transparent electrode 150 to the first buffer layer 242.

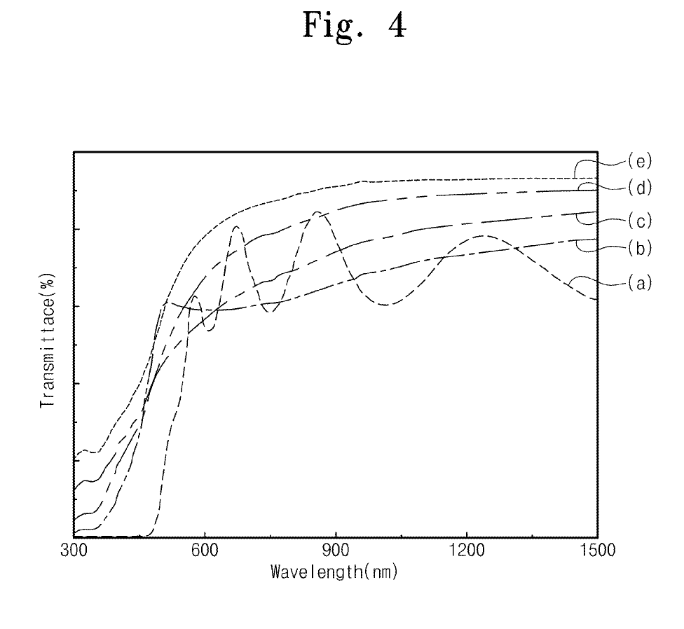

FIG. 4 is a graph illustrating transmittance with respect to the thickness of a copper oxide (Cu_{2+δ}O_{y}) thin film in a thin film solar cell according to an embodiment of the inventive concept.

Referring to FIG. 4, the thickness of the copper oxide (Cu_{2+δ}O_{y}) thin film may be (A) 400 nm, (B) 100 nm, (C) 70 nm, (D) 50 nm, and (E) 30 nm. For the copper oxide (Cu_{2+δ}O_{y}) thin films having the thickness of (B), (C), (D) and (E) except for (A) were confirmed to have the transmittance of about 60% or above for visible light and infrared light. In addition, the transmittance increases as the thickness of the copper oxide (Cu_{2+δ}O_{y}) thin film decreases.

As illustrated in FIGS. 1 and 2, light may incident to the front transparent electrode 150 of the thin film solar cells 100 and 200, penetrate through the buffer layers 140 and 240, and be absorbed by the light absorbing layer 130. That is, the buffer layer is necessary to be transparent. The copper oxide (Cu_{2+δ}O_{y}) thin film is transparent, and may be used as the buffer layer of the thin film solar cells 100 and 200.

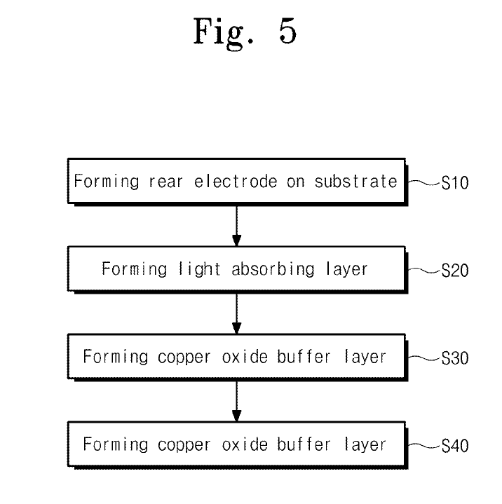

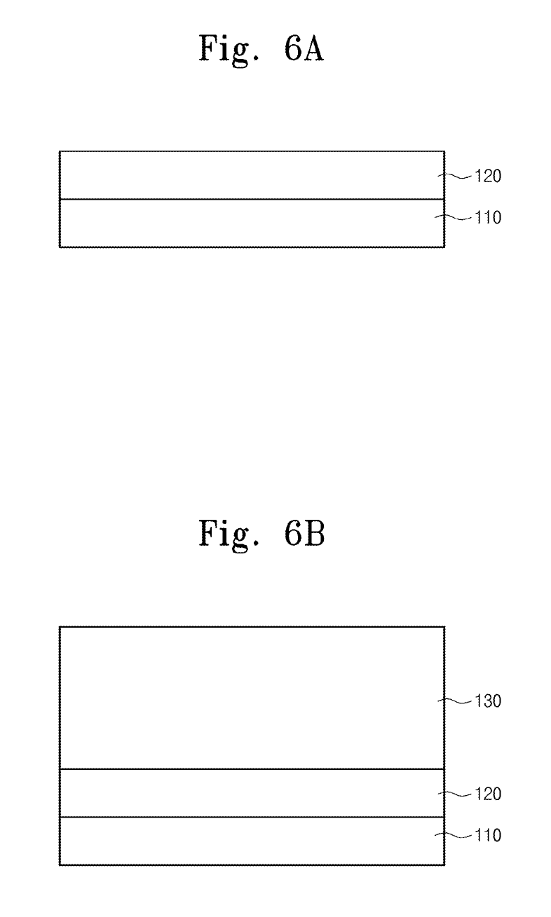

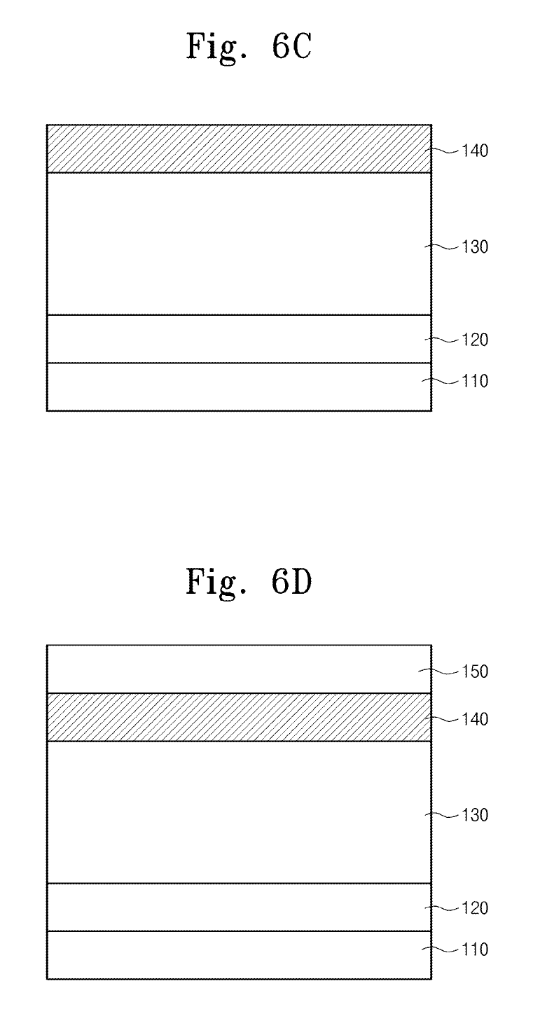

FIG. 5 is a flowchart illustrating a method of manufacturing a thin film solar cell according to an embodiment of the inventive concept. FIGS. 6A to 6D are cross-sectional views illustrating a method of manufacturing a thin film solar cell according to an embodiment of the inventive concept.

Referring to FIG. 5 and FIG. 6A, a rear electrode is formed on a substrate 110 (Step S10).

The substrate 110 may be formed as one of a sodalime glass substrate, a ceramic substrate such as alumina, a metal substrate such as stainless steel, and a copper tape, and a polymer film. In an embodiment of the inventive concept, the substrate 110 may be formed by using sodalime glass.

The rear electrode 120 may be formed by using a material having a low specific resistance, and not inducing the generation of exfoliation phenomenon from the substrate 110 due to the difference of thermal expansion coefficient with respect to the substrate 110. The rear electrode 120 may be formed by using, for example, Mo. Mo has high electric conductivity, forming properties of ohmic contact with other thin film, and stability at a high temperature in a selenium (Se) atmosphere. The rear electrode 120 may be formed by using a sputtering method, for example, a direct current (DC) sputtering method.

Referring to FIG. 5 and FIG. 6B, a light absorbing layer 130 may be formed on the rear electrode 120 (Step S20). The light absorbing layer 130 may be a CIGS-based light absorbing layer formed by using, for example, CuInSe₂, Cu(In,Ga)Se₂, Cu(Al,In)Se₂, Cu(Al,Ga)Se₂, Cu(In,Ga)(S,Se)₂, (Au,Ag,Cu)(In,Ga,Al)(S,Se)₂. In another embodiment of the inventive concept, the light absorbing layer 130 may be a CZTS-based light absorbing layer including, for example, Cu₂ZnSnS₄. The light absorbing layer 130 may be a chalcopyrite-based compound semiconductor. The light absorbing layer 130 may have an energy band gap of from about 1.15 eV to about 1.2 eV.

The light absorbing layer 130 may be formed by means of a physical method or a chemical method. The physical method may be an evaporation method or a mixed method of sputtering and selenization. The chemical method may be, for example, an electroplating method.

Alternatively, the light absorbing layer 130 may be formed by a co-evaporation method, or by synthesizing nano-size particles (powder, colloid, etc.) on the rear electrode 120, mixing the particles with a solvent, screen printing, and reaction sintering.

Referring to FIG. 5 and FIG. 6C, a buffer layer 140 is formed on the light absorbing layer 130.

The buffer layer 140 may be formed by using copper oxide (CuₓO_{y}). X in the copper oxide (CuₓO_{y}) may be 0<x≦2.5, and y in the copper oxide (CuₓO_{y}) may be 0<y≦1.5. The buffer layer 140 may be formed to a thickness of from about 5 nm to about 1,000 nm Preferably, the buffer layer 140 may be formed to a thickness of from about 5 nm to about 100 nm. The copper oxide (CuₓO_{y}) of the buffer layer 140 may have an energy band gap of from about 1.5 eV to about 2.8 eV. The buffer layer 140 may be formed by using one method among a sputtering deposition method, an evaporation method, a chemical bath deposition method, an atomic layer deposition method, and a chemical vapor deposition method. When the buffer layer 140 is formed for mass production, the buffer layer 140 may preferably be formed by the sputtering deposition method.

In an embodiment of the inventive concept, the buffer layer 140 may be formed by a sputtering deposition method. The deposition conditions of the sputtering deposition method may include a deposition temperature, the flowing rate of injected oxygen and nitrogen, a deposition pressure, a deposition power, the temperature of subsequent thermal treatment, and a gas atmosphere. More particularly, the copper oxide (CuₓO_{y}) may be formed at the deposition temperature of from about room temperature (25° C.) to about 250° C., in the oxygen flow rate of from about 0 sccm to about 50 sccm, in the nitrogen flow rate of from about 0 sccm to about 25 sccm, under the pressure of from about 10 mtorr to about 300 mtorr, with the power of from about 18 W to about 100 W, at the heat treatment temperature of from about 200° C. to about 500° C., and in an atmosphere of argon, nitrogen, oxygen or vacuum. The energy band gap, the resistance, the transmittance, and the refractive index of the buffer layer 140 are dependent on x and y of the copper oxide (CuₓO_{y}). X and y of the copper oxide (CuₓO_{y}) may be controlled by adjusting the flowing rate of nitrogen and oxygen, and the deposition power. Thus, the buffer layer 140 having desired properties may be formed.

While forming the buffer layer 140 by means of the sputtering deposition method, the buffer layer 140 in which x and y of the copper oxide (CuₓO_{y}) is gradually increased or decreased may be formed by gradually increasing or decreasing the flow rate of nitrogen and oxygen, and the deposition power. Thus, the buffer layer 140 may be formed to have continuously varying energy band gap or refractive index. The buffer layer 140 may be formed by n-type semiconductor or p-type semiconductor. Generally, the copper oxide (CuₓO_{y}) may illustrate the p-type semiconductor without injection of external dopant. However, the copper oxide (CuₓO_{y}) may have the n-type semiconductor according to the deposition thickness and process conditions.

In another embodiment of the invention, the buffer layer 240 may be formed by stacking the first buffer layer 242 and the second buffer layer 244 on the light absorbing layer 130 one by one. The first buffer layer 242 may include copper oxide (CuₓO_{y}), and the second buffer layer 244 may include ZnS or ZnOS.

Referring to FIG. 5 and FIG. 6D, a front transparent electrode 150 is formed on the buffer layer 140 (Step S40).

The front transparent electrode 150 may be formed by using a material having high light transmittance and high electric conductivity. For example, the front transparent electrode 150 may be formed as a ZnO thin film. The ZnO thin film has an energy band gap of about 3.3 eV and high light transmittance of about 80% or above. In this case, the ZnO thin film may be formed by means of a radio frequency (RF) sputtering method using a ZnO target, a reactive sputtering method using a Zn target, or an organic metal chemical vapor deposition method. The ZnO thin film may be formed by doping aluminum (Al) or boron (B) so as to have low resistance.

On the other hands, the transparent electrode 150 may be formed by stacking an ITO thin film having good electro-optic properties on the ZnO Thin film.

In addition, the front transparent electrode 150 may be formed by stacking an undoped i-type ZnO thin film and an n-type ZnO thin film having low resistance. The ITO thin film may be formed by using a common sputtering method.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. A thin film solar cell, comprising:
a rear electrode formed on a substrate;
a light absorbing layer formed on the rear electrode;
a buffer layer formed on the light absorbing layer; and
a front transparent electrode formed on the buffer layer,
the buffer layer including copper oxide.

2. The thin film solar cell of claim 1, wherein the copper oxide is CuₓO_{y} (0<x≦2.5, and 0<y≦1.5).

3. The thin film solar cell of claim 2, wherein y of the copper oxide is the same in the buffer layer, and x of the copper oxide is gradually increased from an interface of the buffer layer with the front transparent electrode to an interface of the buffer layer with the light absorbing layer.

4. The thin film solar cell of claim 2, wherein y of the copper oxide is the same in the buffer layer, and x of the copper oxide is gradually decreased from an interface of the buffer layer with the front transparent electrode to an interface of the buffer layer with the light absorbing layer.

5. The thin film solar cell of claim 3, wherein the buffer layer has refractive index, the refractive index of the buffer layer being increased as an increase of x of the copper oxide.

6. The thin film solar cell of claim 1, wherein the buffer layer has an energy band gap of from about 1.15 eV to about 2.8 eV.

7. The thin film solar cell of claim 6, wherein the buffer layer has gradually increasing energy band gap from an interface of the buffer layer with the front transparent electrode to an interface of the buffer layer with the light absorbing layer.

8. The thin film solar cell of claim 6, wherein the buffer layer has gradually decreasing energy band gap from an interface of the buffer layer with the front transparent electrode to an interface of the buffer layer with the light absorbing layer.

9. The thin film solar cell of claim 1, wherein the buffer layer has n-type semiconductor properties, migration of electrons being easier than migration of holes from the light absorbing layer to the buffer layer.

10. The thin film solar cell of claim 1, wherein the buffer layer has p-type semiconductor properties, migration of holes being easier than migration of electrons from the light absorbing layer to the buffer layer.

11. The thin film solar cell of claim 1, wherein the buffer layer comprises a first buffer layer and a second buffer layer stacked on the light absorbing layer one by one, the first buffer layer comprising copper oxide.

12. The thin film solar cell of claim 11, wherein the second buffer layer comprises ZnS or ZnOS.
